(19) United States
(12) Patent Application Publication
(10) Pub. No.: US 2025/0362818 A1
(43) Pub. Date: Nov. 27, 2025

(54) MEMORY DEVICE AND OPERATING METHOD THEREOF

(71) Applicant: SAMSUNG ELECTRONICS CO., LTD., Suwon-si (KR)

(72) Inventors: Seungki Hong, Suwon-si (KR); Kiheung Kim, Suwon-si (KR); Hoseok Seol, Suwon-si (KR); Changsik Yoo, Suwon-si (KR); Dongkeon Lee, Suwon-si (KR); Minsoo Jang, Suwon-si (KR); Wonho Choi, Suwon-si (KR); Jinyong Choi, Suwon-si (KR)

(21) Appl. No.: 19/029,930

(22) Filed: Jan. 17, 2025

(30) Foreign Application Priority Data
May 22, 2024 (KR) 10-2024-0066597

(51) Int. Cl. G06F 3/06

(52) U.S. Cl. CPC G06F 3/0625; G06F 3/0659; G06F 3/0673

(57) ABSTRACT

A memory device and an operating method thereof are provided. The memory device includes a memory cell array including a first memory bank and a second memory bank, a control logic configured to control operations of the memory cell array and generate a master enable signal and a master disable signal, a first repair circuit configured to perform a repair operation on memory cells of the first memory bank, and a second repair circuit configured to perform a repair operation on memory cells of the second memory bank. When the memory device is operating in a normal mode, the first repair circuit performs the repair operation, based on the master enable signal, and the second repair circuit does not perform the repair operation, based on the master disable signal.

### CROSS-REFERENCE TO RELATED APPLICATION

This application is based on and claims priority under 35 U.S.C. § 119 to Korean Patent Application No. 10-2024-0066597, filed on May 22, 2024, in the Korean Intellectual Property Office, the disclosure of which is incorporated by reference herein in its entirety.

### BACKGROUND

In memory devices, operating current refers to current consumed when memory devices operate in a normal mode, such as a read mode or a write mode. Contrarily, standby current refers to current consumed or leaked when memory devices operate in a standby mode or a test mode. In general, while a memory device is operating in a standby mode, peripheral circuits of the memory device are deactivated (or not used). In other words, while the memory device is operating in the standby mode, power applied to peripheral circuits of the memory device is cut off to stop the operation of the peripheral circuits.

When the memory device changes from the standby mode or the test mode to the normal mode, leakage current may occur as power is resupplied to the peripheral circuits.

As the integration density of memory devices increases, the capacitance of nodes of memory cells decreases, and accordingly, soft errors in which data of the nodes of the memory cells changes increase. Here, soft errors refer to phenomena in which data stored in a memory cell is changed by cosmic rays such as alpha particles.

Therefore, it is desired to reduce leakage current occurring as a result of a memory device switching to a normal mode and a memory cell allowing soft errors to be improved.

### SUMMARY

This disclosure provides a memory device having a control logic that generates and provides a master disable signal to an unused circuit when the memory device operates in a normal mode. In other words, a memory device is provided which is capable of reducing leakage current in an unused circuit by using a control logic that controls a master disable signal and an operating method of the memory device.

According to implementations, there is provided a memory device including a memory cell array including a first memory bank and a second memory bank, a control logic configured to control operations of the memory cell array and generate a master enable signal and a master disable signal, a first repair circuit configured to perform a repair operation on memory cells of the first memory bank, and a second repair circuit configured to perform a repair operation on memory cells of the second memory bank, wherein, when the memory device is operating in a normal mode, the first repair circuit performs a repair operation, based on the master enable signal, and the second repair circuit does not perform a repair operation, based on the master disable signal.

According to other implementations, there is provided a memory device including a memory cell array including a plurality of memory cells, a control logic configured to control operations of the memory cell array and generate a master enable signal and a master disable signal, and a first circuit configured to perform an operation on the plurality of memory cells, wherein, when the memory device is operating in a normal mode, the first circuit performs the operation, based on the master enable signal, and the first circuit does not perform the operation, based on the master disable signal.

According to further implementations, there is provided an operating method of a memory device. The operating method includes applying a power supply voltage to the memory device according to power-on of the memory device, generating and outputting a master enable signal and a master disable signal, based on the power supply voltage, performing an operation of the memory device, based on the master enable signal, and not performing the operation of the memory device, based on the master disable signal.

### BRIEF DESCRIPTION OF THE DRAWINGS

Implementations will be more clearly understood from the following detailed description taken in conjunction with the accompanying drawings in which:

FIG. 1 is a block diagram of a memory system according to implementations;

FIG. 2 is a block diagram of a memory device according to implementations;

FIG. 3 is a block diagram of a control logic according to implementations;

FIG. 4 is a block diagram of a fuse circuit according to implementations;

FIG. 5 is a circuit diagram illustrating a content-addressable memory (CAM) cell according to implementations;

FIG. 6 is a circuit diagram of a fail address memory of a CAM cell, according to implementations;

FIG. 7 is a diagram illustrating an operating method of a repair circuit, according to implementations;

FIG. 8 is a flowchart of an operating method of a memory device, according to implementations;

FIG. 9 is a flowchart of an operating method of a repair circuit, according to implementations;

FIG. 10 is a block diagram of a memory system according to implementations;

FIG. 11 is a block diagram of a memory device according to implementations;

FIG. 12 is a block diagram of a system-on-chip according to implementations; and

FIG. 13 is a block diagram of a system illustrating an electronic device including a memory device, according to implementations.

### DETAILED DESCRIPTION

Hereinafter, implementations are described in detail with reference to the accompanying drawings.

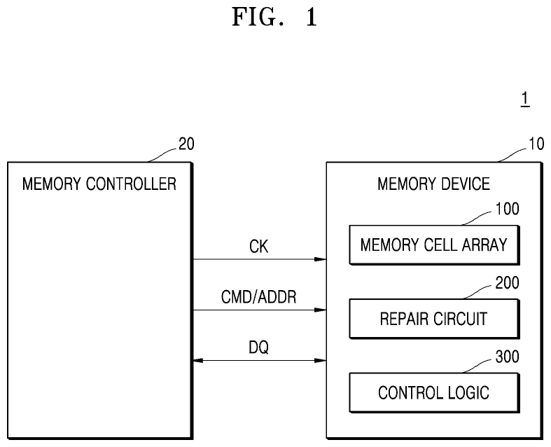

FIG. 1 is a block diagram of a memory system 1 according to implementations.

Referring to FIG. 1, the memory system 1 may include a memory controller 20 and a memory device 10. The memory device 10 may include a memory cell array 100, a repair circuit 200, and a control logic 300.

The memory system 1 may be coupled to a host and accessed by the host. The memory system 1, as a functional block that performs general computer operations in an electronic device, may correspond to a central processing unit (CPU), a digital signal processor (DSP) a graphics processing unit (GPU), or an application processor (AP).

The memory controller 20 may generally control operations of the memory system 1 and data exchange between an external host and the memory device 10. For example, the memory controller 20 may control the memory device 10 to write data or read data, according to the request of a host. The memory controller 20 may apply an operating command for controlling the memory device 10 and may control operation of the memory device 10.

The memory controller 20 may transmit a clock signal CK, a command CMD, and an address ADDR to the memory device 10 and may exchange data DQ with the memory device 10.

The memory device 10 may include, for example, dynamic random-access memory (DRAM) but is not limited thereto. For example, the memory device 10 may correspond to double data rate (DDR) synchronous DRAM (SDRAM), low power DDR (LPDDR) SDRAM, graphics DDR (GDDR) SDRAM, or Rambus DRAM (RDRAM). The memory device 10 may be implemented by static DRAM, high bandwidth memory (HBM), or processor-in-memory (PIM).

The memory cell array 100 may include a plurality of rows, a plurality of columns, and a plurality of memory cells at intersections between the rows and columns. The memory cells of the memory cell array 100 may include volatile memory cells, e.g., DRAM cells. The memory cell array 100 may also include redundancy rows and/or redundancy columns, which are connected to redundancy memory cells used to repair a fail memory cell when a defect or failure occurs in a memory cell.

The control logic 300 may control access to the memory cell array 100, based on the command CMD and the address ADDR. The control logic 300 may generally control operations of the memory device 10. The control logic 300 may generate and output a master enable signal and/or a master disable signal in response to the command CMD. For example, the master enable signal may be provided to a circuit, which is used when the memory device 10 operates in the normal mode, to control the circuit to operate. The master disable signal may be provided to a circuit, which is not used when the memory device 10 operates in the normal mode, to control the circuit not to operate. For example, the master enable signal (MASTER_EN) and/or the master disable signal (MASTER_DIS) may be defined based on the output state of the control logic 300.

The repair circuit 200 may be configured to repair fail memory cells, which are detected in the memory cell array 100, with redundancy memory cells. The repair circuit 200 may perform a repair operation based on control signals generated by the control logic 300 and may replace a fail row address and/or a fail column address with a redundancy row address and/or a redundancy column address, respectively.

According to implementations, the control logic 300 of the memory device 10 may generate and output control signals (e.g., a master enable signal and a master disable signal). When the memory device 10 operates in the normal mode, the control logic 300 may block leakage current to an unused circuit by controlling control signals.

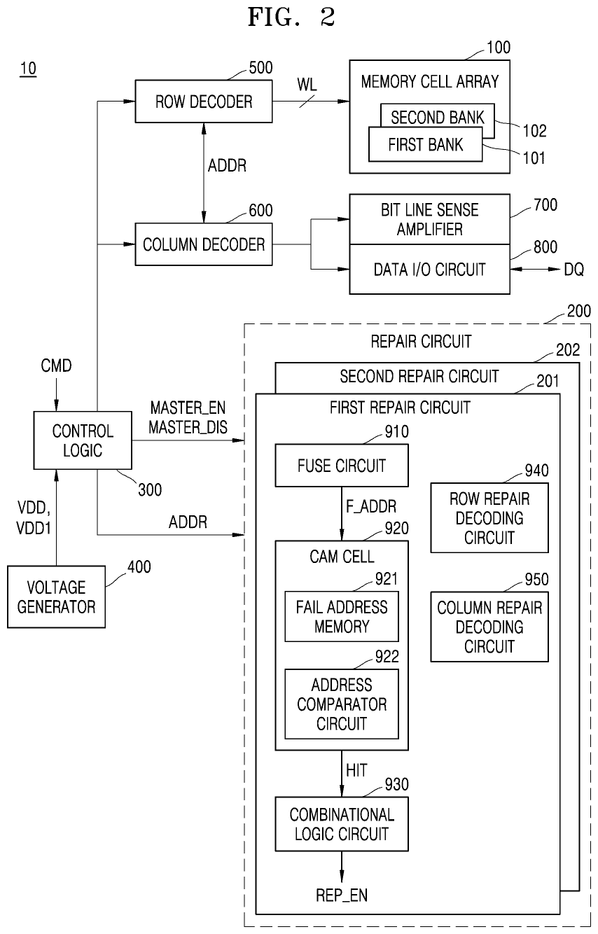

FIG. 2 is a block diagram of the memory device 10 according to implementations.

The memory device 10 may include the memory cell array 100, the control logic 300, the repair circuit 200, a voltage generator 400, a row decoder 500, a column decoder 600, a bit line sense amplifier 700, and a data input/output (I/O) circuit 800.

The memory cell array 100 may include a first memory bank 101 and a second memory bank 102. The row decoder 500 and the column decoder 600 may be provided in correspondence to each of the first memory bank 101 and the second memory bank 102. The row decoder 500 and the column decoder 600, which are connected to a bank corresponding to a bank address, may be activated. Each of the first memory bank 101 and the second memory bank 102 may include a plurality of memory cells in a matrix of rows and columns and redundancy memory cells connected to redundancy rows and/or redundancy columns.

The control logic 300 may receive the command CMD and the address ADDR from the memory controller 20 (in FIG. 1) through a channel and may generate control signals corresponding to the command CMD. The control logic 300 may generally control operations of the memory device 10. For example, a memory operation may be performed according to the operation timing of the control logic 300. The control logic 300 may also decode the command CMD and internally generate and output a decoded command signal. For example, the control logic 300 may generate and output a master enable signal MASTER_EN and/or a master disable signal MASTER_DIS in response to the command CMD.

Here, the master enable signal MASTER_EN may refer to a control signal, which allows each circuit of the memory device 10 to operate when the memory device 10 operates in the normal mode. For example, when the memory device 10 operates in the normal mode, the repair circuit 200 may receive the master enable signal MASTER_EN and perform a repair operation in response to the master enable signal MASTER_EN.

The master disable signal MASTER_DIS may refer to a control signal, which does not allow each circuit of the memory device 10 to operate when the memory device 10 operates in the normal mode. For example, when the memory device 10 operates in the normal mode, the repair circuit 200 may receive the master disable signal MASTER_DIS and may not perform a repair operation in response to the master disable signal MASTER_DIS.

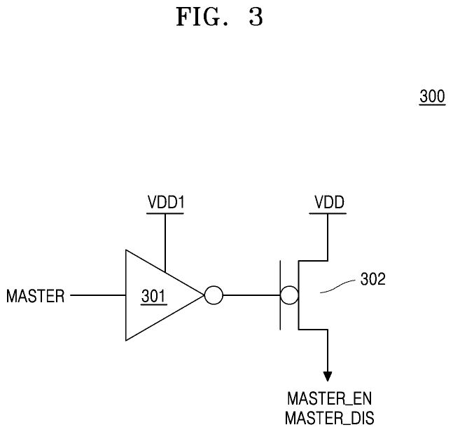

The configuration of the control logic 300 is described in detail with reference to FIG. 3 below.

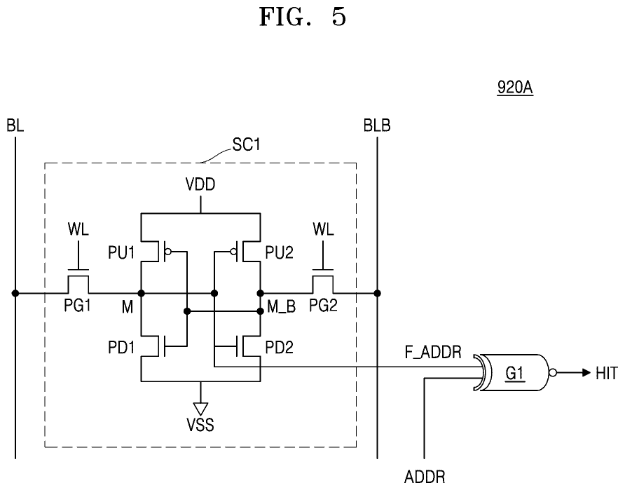

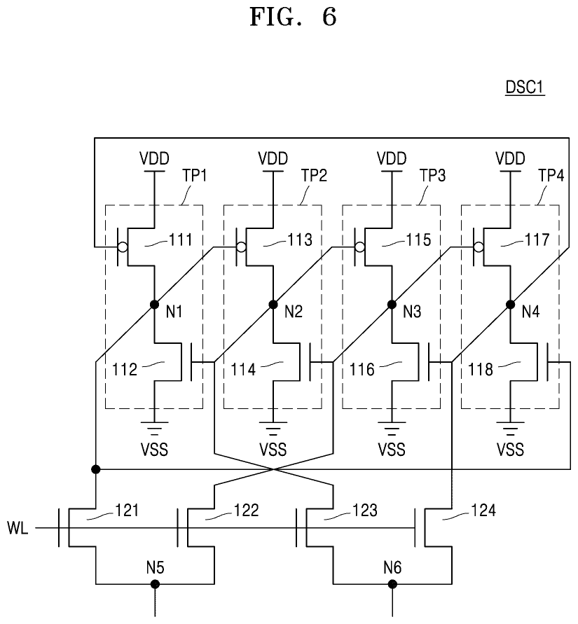

The repair circuit 200 may include a first repair circuit 201 corresponding to the first memory bank 101 and a second repair circuit 202 corresponding to the second memory bank 102. Each of the first repair circuit 201 and the second repair circuit 202 may include a fuse circuit 910, a content-addressable memory (CAM) cell 920, a combinational logic circuit 930, a row repair decoding circuit 940, and a column repair decoding circuit 950. The CAM cell 920 may include a fail address memory 921 and an address comparator circuit 922. The configuration of the CAM cell 920 is described in detail with reference to FIGS. 5 and 6 below.

The fuse circuit 910 may provide a fail address F_ADDR to the CAM cell 920. The fail address F_ADDR may be stored in the fail address memory 921. The address comparator circuit 922 may compare the fail address F_ADDR with the address ADDR and may generate and output a hit signal HIT. The combinational logic circuit 930 may generate and output a repair enable signal REP_EN based on the hit signal HIT.

Based on repair control signals generated by the repair circuit 200, the row repair decoding circuit 940 and the column repair decoding circuit 950 may perform a repair operation such that a redundancy address is selected instead of a fail address. Each of the first repair circuit 201 and the second repair circuit 202 may replace a fail address of a bank with a redundancy address by using the row repair decoding circuit 940 and the column repair decoding circuit 950.

The repair circuit 200 may receive the address ADDR. The repair circuit 200 may receive the master enable signal MASTER_EN and/or the master disable signal MASTER_DIS from the control logic 300. For example, when the memory device 10 operates in the normal mode, the first repair circuit 201 may receive the master enable signal MASTER_EN from the control logic 300 and the second repair circuit 202 may receive the master disable signal MASTER_DIS from the control logic 300. In this case, the first repair circuit 201 may perform a repair operation, and the second repair circuit 202 may not perform a repair operation. Here, the first repair circuit 201 may be referred to as a used circuit, and the second repair circuit 202 may be referred to as an unused circuit.

According to implementations, the control logic 300 may generate and provide the master disable signal MASTER_DIS to an unused circuit when the memory device 10 operates in the normal mode. Accordingly, the control logic 300 may reduce leakage current to an unused circuit by controlling the master disable signal MASTER_DIS, thereby reducing power consumption of the memory device 10.

The voltage generator 400 may generate a voltage necessary for operation of the memory device 10. The voltage generator 400 may generate and provide a power supply voltage VDD and a first power supply voltage VDD1 to the control logic 300. For example, the level of the power supply voltage VDD may be higher or lower than the level of the first power supply voltage VDD1. According to implementations, whether the level of the power supply voltage VDD is higher or lower than the level of the first power supply voltage VDD1 may be changed.

The row decoder 500 may receive the address ADDR from the outside (e.g., the memory controller 20 in FIG. 1). The row decoder 500 may be connected to the memory cell array 100 through word lines WL. The row decoder 500 may select one of the word lines WL under control by the control logic 300. For example, in the normal operation, the row decoder 500 may apply a write/read voltage to the memory cell array 100.

The column decoder 600 may receive the address ADDR from the outside. The column decoder 600 may decode the address ADDR and select one bit line corresponding to the address ADDR from among a plurality of bit lines.

The bit line sense amplifier 700 may write data to the memory cell array 100 or read data from the memory cell array 100. The bit line sense amplifier 700 may be connected to a selected bit line according to the address ADDR.

The data I/O circuit 800 may provide the data DQ read from the memory cell array 100 to the outside of the memory device 10, e.g., the memory controller 20 (in FIG. 1), or may provide the data DQ from the outside to the bit line sense amplifier 700.

According to implementations, when the memory cell array 100 operates in the normal mode, the control logic 300 may generate and provide the master disable signal MASTER_DIS to an unused circuit. In other words, the control logic 300 may reduce leakage current to an unused circuit by controlling the master disable signal MASTER_DIS, thereby reducing power consumption of the memory device 10.

FIG. 3 is a block diagram of the control logic 300 according to implementations.

Referring to FIG. 3, the control logic 300 may include a first inverter 301 and a first transistor 302. The first inverter 301 may invert a master signal MASTER. The first inverter 301 may be driven with the first power supply voltage VDD1. The first transistor 302 may be driven with the power supply voltage VDD. The first transistor 302 may output the master enable signal MASTER_EN and/or the master disable signal MASTER_DIS according to an output of the first inverter 301. Although it is illustrated that the first transistor 302 is a P-type transistor, implementations are not limited thereto. The first transistor 302 may be implemented as an N-type transistor. For example, the master enable signal (MASTER_EN) and/or the master disable signal (MASTER_DIS) may be defined based on the output state of the first inverter 301.

For example, when the level of the first power supply voltage VDD1 applied to the first inverter 301 is higher than the level of the power supply voltage VDD applied to an end of the first transistor 302, the first transistor 302 may be turned on and may output the master enable signal MASTER_EN. In other words, when the level of the first power supply voltage VDD1 is higher than the level of the power supply voltage VDD, the control logic 300 may output the master enable signal MASTER_EN.

When the level of the first power supply voltage VDD1 applied to the first inverter 301 is lower than the level of the power supply voltage VDD applied to an end of the first transistor 302, the first transistor 302 may be turned off and may output the master disable signal MASTER_DIS. In other words, when the level of the first power supply voltage VDD1 is lower than the level of the power supply voltage VDD, the control logic 300 may output the master disable signal MASTER_DIS.

Here, referring to FIGS. 2 and 3, the master enable signal MASTER_EN may refer to a control signal allowing the repair circuit 200 to perform a repair operation when the memory device 10 operates in the normal mode. The master disable signal MASTER_DIS may refer to a control signal not allowing the repair circuit 200 to perform a repair operation when the memory device 10 operates in the normal mode.

For example, when the memory device 10 operates in the normal mode, the repair circuit 200 may or may not perform a repair operation. In other words, when the memory device 10 operates in the normal mode, the repair circuit 200 that receives the master enable signal MASTER_EN and performs a repair operation may be referred to as a used circuit, and the repair circuit 200 that receives master disable signal MASTER_DIS and does not perform a repair operation may be referred to as an unused circuit.

According to implementations, the control logic 300 may generate and output the master enable signal MASTER_EN and/or the master disable signal MASTER_DIS. The control logic 300 may block leakage current to an unused circuit by providing the master disable signal MASTER_DIS to the unused circuit when the memory device 10 operates in the normal mode. Accordingly, power consumption may be reduced when the memory device 10 operates in the normal mode.

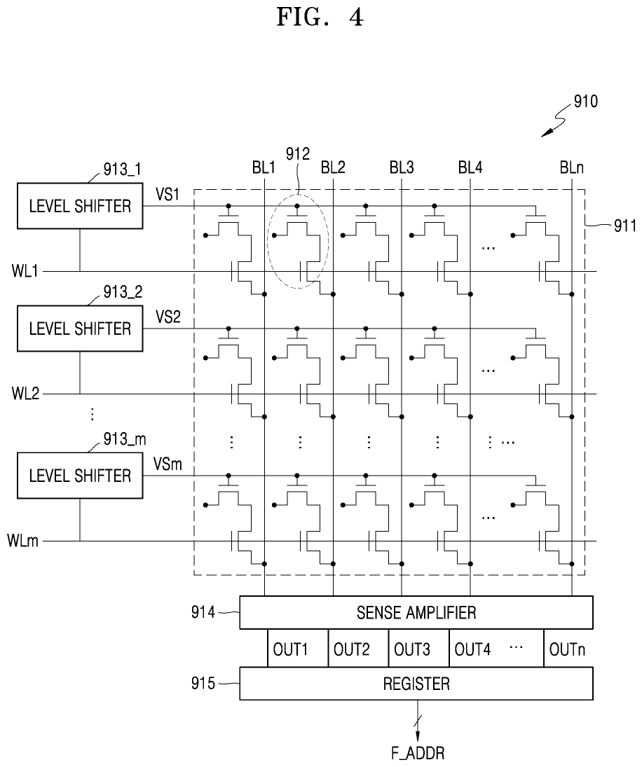

FIG. 4 is a block diagram of the fuse circuit 910 according to implementations.

Referring to FIG. 4, the fuse circuit 910 may include a fuse array 911 including a plurality of anti-fuses 912, level shifters 913_1 to 913_m generating a high voltage to change the resistance state of the anti-fuses 912, and a sense amplifier 914 sensing and amplifying information stored in the fuse array 911. A register 915 storing fuse data generated by reading information stored in the fuse array 911 may be included in the fuse circuit 910.

The fuse array 911 may include a plurality of fuses, and information may be stored in each fuse. The fuse array 911 may include a laser fuse the connection of which is controlled by laser radiation or an electrical fuse the connection of which is controlled by an electrical signal. Alternatively, the fuse array 911 may include an anti-fuse the state of which is changed from a high-resistance state to a low-resistance state by an electrical signal (e.g., a high-voltage signal). The fuse array 911 may include any one of the various types of fuses. In the implementations described below, it is assumed that the fuse array 911 is an anti-fuse array including anti-fuses. The fuse array 911 may interchangeably be used with an anti-fuse array 911. Information stored in an anti-fuse or data read from an anti-fuse may be referred to as fuse data.

The anti-fuse array 911 may have an array structure in which the anti-fuses 912 are arranged at intersections between rows and columns. For example, when the anti-fuse array 911 has “m” rows and “n” columns, the anti-fuse array 911 may have m*n anti-fuses 912. The anti-fuse array 911 may include “m” word lines WL1 to WLm to access anti-fuses 912 in “m” rows and “n” bit lines BL1 to BLn arranged in correspondence to “n” columns to transmit information read from the anti-fuses 912.

The anti-fuse array 911 may be programmed by changing the state of the anti-fuses 912 by applying voltage signals VS1 to VSm from the level shifters 913_1 to 913_m to the anti-fuse array 911. Each of the anti-fuses 912 may start in a high-resistance state and may change to a low-resistance state by a programming operation, thereby storing information. Each anti-fuse 912 may have a structure, i.e., a capacitor structure, which includes two conductive layers and a dielectric layer between the conductive layers, and may be programmed by breaking down the dielectric layer by applying a high voltage between the conductive layers.

After the anti-fuse array 911 is programmed, a read operation of the anti-fuse array 911 may be performed when the memory device 10 starts to be driven. The read operation of the anti-fuse array 911 may be simultaneously performed with the driving of the memory device 10 or may be performed a certain time after the memory device 10 is driven. A word line selection signal may be provided to the anti-fuse array 911 through the word lines WL1 to WLm of the anti-fuse array 911, and information stored in a selected anti-fuse 912 may be provided to the sense amplifier 914 through the bit lines BL1 to BLn. Due to the nature of the array structure, information of the anti-fuse array 911 may be randomly accessed by driving the word lines WL1 to WLm and the bit lines BL1 to BLn.

For example, as the word lines WL1 to WLm are sequentially driven, the anti-fuses 912 of the anti-fuse array 911 may be sequentially accessed starting from the first row to the m-th row. Information of the anti-fuses 912 sequentially accessed may be provided to the sense amplifier 914. The sense amplifier 914 may include at least one sense amplification circuit. For example, when the anti-fuse array 911 has “n” columns, the sense amplifier 914 may include “n” sense amplification circuits in correspondence to the “n” columns. The “n” sense amplification circuit may be respectively connected to the “n” bit lines BL1 to BLn.

The sense amplifier 914 may sense and amplify information of the anti-fuse array 911 and output fuse data OUT1 to OUTn. The fuse data OUT1 to OUTn output from the sense amplifier 914 may be provided to the register 915. The register 915 may receive the fuse data OUT1 to OUTn in units of rows in the anti-fuse array 911. For example, when one of the rows in the anti-fuse array 911 is selected, the fuse data OUT1 to OUTn from anti-fuses 912 connected to a word line corresponding to the selected row may be provided in parallel to the register 915. The fuse data OUT1 to OUTn stored in the register 915 may correspond to information for a repair operation, e.g., the fail address F_ADDR indicating a fail row address and/or a fail column address.

FIG. 5 is a circuit diagram illustrating a CAM cell 920A according to implementations.

FIG. 5 is a circuit diagram illustrating one CAM cell 920A among a plurality of CAM cells included in the first repair circuit 201 corresponding to the first memory bank 101. The CAM cell 920A, a static random-access memory (SRAM) cell SC1, and an exclusive OR (XOR) gate G1 in FIG. 5 may respectively correspond to the CAM cell 920, the fail address memory 921, and the address comparator circuit 922 in FIG. 2.

Referring back to FIG. 5, the CAM cell 920A may include the SRAM cell SC1 and the XOR gate G1.

For example, the CAM cell 920A may be widely used in applications, such as networking, imaging, and voice recognition applications, which require very fast searches on databases.

Referring FIGS. 2 and 5, the fail address memory 921 may be connected to a word line WL, a bit line BL, and a complementary bit line BLB. The fail address memory 921 may store the fail address F_ADDR. The fail address memory 921 may be formed as the SRAM cell SC1.

The SRAM cell SC1 include a pair of cross-coupled inverters between a node, to which a positive supply voltage, e.g., the power supply voltage VDD, is applied, and a node, to which a negative supply voltage, e.g., a ground voltage VSS, is applied. For example, the first inverter in the pair of cross-coupled inverters may include a pull-up transistor PU1 and a pull-down transistor PD1, and the second inverter in the pair of cross-coupled inverters may include a pull-up transistor PU2 and a pull-down transistor PD2.

A first storage node M between the pull-up transistor PU1 and the pull-down transistor PD1 may be connected to the gates of the pull-up transistor PU2 and the pull-down transistor PD2. A first complementary storage node M_B between the pull-up transistor PU2 and the pull-down transistor PD2 may be connected to the gates of the pull-up transistor PU1 and the pull-down transistor PD1.

The SRAM cell SC1 may further include transfer transistors PG1 and PG2 configured to respectively connect the first inverter and the second inverter to the bit line BL and the complementary bit line BLB according to the word line WL that is activated (e.g., the word line WL having a high-level voltage). In this case, the first storage node M may be connected to the bit line BL through the transfer transistor PG1, and the first complementary storage node M_B may be connected to the complementary bit line BLB through the transfer transistor PG2. For example, each of the pull-up transistors PU1 and PU2 may include a P-type transistor, and each of the pull-down transistors PD1 and PD2 and the transfer transistors PG1 and PG2 may include an N-type transistor.

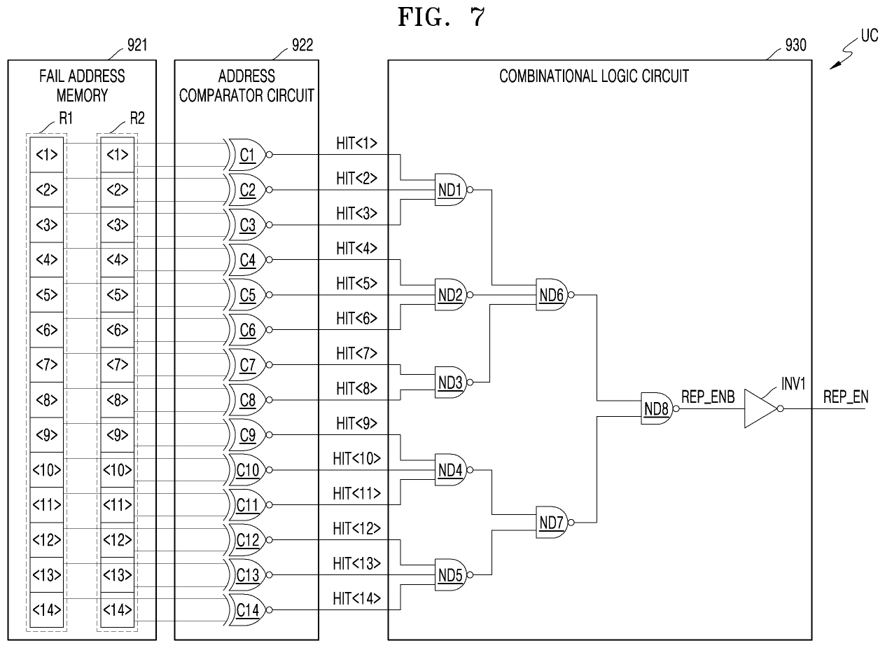

Referring to FIGS. 2 and 5, the address comparator circuit 922 may be formed as the XOR gate G1. The XOR gate G1 may compare the address ADDR with the fail address F_ADDR and output a result of the comparison. When the fail address F_ADDR matches the address ADDR as the result of the comparison, a match may occur. When the fail address F_ADDR does not match the address ADDR as the result of the comparison, a mismatch may occur. For example, referring to FIG. 7, when the fail address F_ADDR matches the address ADDR, the hit signal HIT may be output at a high logic level. When fail address F_ADDR does not match the address ADDR, the hit signal HIT may be output at a low logic level.

According to implementations, the control logic may generate the master enable signal MASTER_EN and/or the master disable signal MASTER_DIS and may block leakage current to an unused circuit by providing the master disable signal MASTER_DIS to the unused circuit when the memory device 10 operates in the normal mode. Accordingly, power consumption may be reduced when the memory device 10 operates in the normal mode.

FIG. 6 is a circuit diagram of a fail address memory DSC1 of a CAM cell, according to implementations.

FIG. 6 is a circuit diagram illustrating one CAM cell 920 among a plurality of CAM cells included in the first repair circuit 201 corresponding to the first memory bank 101 in FIG. 2. The fail address memory DSC1 of the CAM cell of FIG. 6 may correspond to the fail address memory 921 in FIG. 2.

Referring back to FIG. 6, the fail address memory DSC1 may be formed as a dual interlocked storage cell (DICE) SRAM cell.

The fail address memory DSC1 may include first to fourth transistor pairs TP1, TP2, TP3, and TP4, each including a P-type transistor and an N-type transistor that are connected to each other in series through one of first to fourth nodes N1, N2, N3, and N4. Each of the first to fourth nodes N1, N2, N3, and N4 may be connected to the gate of an N-type transistor in a preceding transistor pair and the gate of a P-type transistor in a succeeding transistor pair.

The first transistor pair TP1 may include a first P-type transistor 111 and a first N-type transistor 112. The first P-type transistor 111 may include a source connected to the power supply voltage VDD, a gate connected to the fourth node N4, and a drain connected to the first node N1. The first N-type transistor 112 may include a drain connected to the first node N1, a gate connected to the second node N2, and a source connected to the ground voltage VSS.

The second transistor pair TP2 may include a second P-type transistor 113 and a second N-type transistor 114. The second P-type transistor 113 may include a source connected to the power supply voltage VDD, a gate connected to the first node N1, and a drain connected to the second node N2. The second N-type transistor 114 may include a drain connected to the second node N2, a gate connected to the third node N3, and a source connected to the ground voltage VSS.

The third transistor pair TP3 may include a third P-type transistor 115 and a third N-type transistor 116. The third P-type transistor 115 may include a source connected to the power supply voltage VDD, a gate connected to the second node N2, and a drain connected to the third node N3. The third N-type transistor 116 may include a drain connected to the third node N3, a gate connected to the fourth node N4, and a source connected to the ground voltage VSS.

The fourth transistor pair TP4 may include a fourth P-type transistor 117 and a fourth N-type transistor 118. The fourth P-type transistor 118 may include a source connected to the power supply voltage VDD, a gate connected to the third node N3, and a drain connected to the fourth node N4. The fourth N-type transistor 118 may include a drain connected to the fourth node N4, a gate connected to the first node N1, and a source connected to the ground voltage VSS.

A first N-type access transistor 121 may include a source connected to the first node N1, a gate connected to the word line WL, and a drain connected to a fifth node N5. A second N-type access transistor 122 may include a source connected to the third node N3, a gate connected to the word line WL, and a drain connected to the fifth node N5.

A third N-type access transistor 123 may include a source connected to the second node N2, a gate connected to the word line WL, and a drain connected to a sixth node N6. A fourth N-type access transistor 124 may include a source connected to the fourth node N4, a gate connected to the word line WL, and a drain connected to the sixth node N6.

The fail address memory DSC1 may include the first N-type access transistor 121, the second N-type access transistor 122, the third N-type access transistor 123, and the fourth N-type access transistor 124, which may access four or two nodes among the first to fourth nodes N1, N2, N3, and N4. In other words, the fail address memory DSC1 may include access transistors connected to at least two of the first to fourth nodes N1, N2, N3, and N4 and may store a data bit in or read a data bit from at least some of the first to fourth nodes N1, N2, N3, and N4, and accordingly, a soft error rate may be improved.

According to implementations, the fail address memory DSC1 may be formed as a DICE SRAM cell. Accordingly, even when a memory device operates in the normal mode, soft error in the memory device may be decreased by dispersing particles.

FIG. 7 is a diagram illustrating an operating method of a repair circuit, according to implementations.

FIG. 7 is a diagram of a unit circuit UC, which generates the repair enable signal REP_EN related to one fail address, among a plurality of unit circuits included in the first repair circuit 201 corresponding to the first memory bank 101.

Referring to FIGS. 2 and 7, the unit circuit UC generating the repair enable signal REP_EN may include the fail address memory 921, the address comparator circuit 922, and the combinational logic circuit 930. The fail address memory 921 may include a first register R1 and a second register R2. The address comparator circuit 922 may include XNOR logic circuits C1 to C14. The combinational logic circuit 930 may include NAND logic circuits ND1 to ND8 and an inverter circuit INV1. For example, the unit circuit UC may include circuits that operate with a 14-bit row address RA[14:1] in which a low-order 1-bit row address RA[0] is excluded from a 15-bit row address RA[14:0]. The present embodiment is not limited to the unit circuit UC for the 14-bit row address RA[14:1]. According to implementations, a unit circuit may be used with an address consisting of fewer or more bits than the number of bits of the address used in the present example implementation.

In implementations, each of the first memory bank 101 and the second memory bank 102 of the memory cell array 100 may include a plurality of memory blocks, which are connected to word lines corresponding to a row address RA[15:0], and main word line drivers and sub word line drivers, which are respectively connected to the memory blocks. The main word line drivers may be connected to a row decoder, may activate main word line drive signals corresponding to decoded 14-bit row address RA[14:1], and may activate sub word line drive signals corresponding to a decoded low-order 1-bit row address RA[0]. For example, the sub word line drivers may include an inverter circuit, which includes a P-type transistor and an N-type transistor. A main word line drive signal is connected to the gates of the P-type transistor and the N-type transistor, a sub word line drive signal is connected to the source of the P-type transistor, and a sub word line is connected to the drain of the P-type transistor. According to this structure of the main word line drivers and the sub word line drivers, a word line of each of the first memory bank 101 and the second memory bank 102 may be dominantly activated in response to a main word line drive signal. Accordingly, the word line of each of the first memory bank 101 and the second memory bank 102 may be described as being accessed by the 14-bit row address RA[14:1].

The fail address memory 921 may include the first register R1 and the second register R2, each formed as a register array. The first register R1 may store a first address provided from the fuse circuit 910. The first address may be constituted of 14 bits <14:1>. The second register R2 may store a second address provided from the memory controller 20 (in FIG. 1). Like the first address, the second address may be constituted of 14 bits <14:1>. The bits <14:1> of the first address stored in the first register R1 and the bits <14:1> of the second address stored in the second register R2 may be provided to the address comparator circuit 922.

The address comparator circuit 922 may include the XNOR logic circuits C1 to C14. The XNOR logic circuits C1 to C14 may respectively compare the bits <14:1> of the first address stored in the first register R1 with the bits <14:1> of the second address stored in the second register R2 and may output the hit signal HIT[14:1]. The XNOR logic circuit C1 may compare the value of the bit <1> of the first address with the value of the bit <1> of the second address and output a hit signal HIT<1>. The XNOR logic circuit C2 may compare the value of the bit <2> of the first address with the value of the bit <2> of the second address and output a hit signal HIT<2>. The XNOR logic circuit C3 may compare the value of the bit <3> of the first address with the value of the bit <3> of the second address and output a hit signal HIT<3>. Similarly, the XNOR logic circuit C12 may compare the value of the bit <12> of the first address with the value of the bit <12> of the second address and output a hit signal HIT<12>. The XNOR logic circuit C13 may compare the value of the bit <13> of the first address with the value of the bit <13> of the second address and output a hit signal HIT<13>. The XNOR logic circuit C14 may compare the value of the bit <14> of the first address with the value of the bit <14> of the second address and output a hit signal HIT<14>.

Each of the hit signals HIT[14:1] of the address comparator circuit 922 may be output at a high logic level when the value of a corresponding one of the bits <14:1> of the first address, which are respectively input to the XNOR logic circuits C1 to C14, matches the value of a corresponding one of the bits <14:1> of the second address, which are respectively input to the XNOR logic circuits C1 to C14, and may be output at a low logic level when the value of a corresponding one of the bits <14:1> of the first address, which are respectively input to the XNOR logic circuits C1 to C14, does not match the value of a corresponding one of the bits <14:1> of the second address, which are respectively input to the XNOR logic circuits C1 to C14. For example, the address comparator circuit 922 may output all the hit signals HIT[14:1] at a high logic level when first address bits stored in the first register R1 match second address bits stored in the second register R2.

The combinational logic circuit 930 may include the NAND logic circuits ND1 to ND8 and the inverter circuit INV1. The NAND logic circuits ND1 to ND8 may receive the hit signals HIT[14:1] from the address comparator circuit 922 and output a pre-repair enable signal REP_ENB. The inverter circuit INV1 may receive the pre-repair enable signal REP_ENB and output the repair enable signal REP_EN. The NAND logic circuit ND1 may receive the hit signals HIT<1>, HIT<2>, and HIT<3>. The NAND logic circuit ND2 may receive the hit signals HIT<4>, HIT<5>, and HIT<6>. The NAND logic circuit ND3 may receive the hit signals HIT<7> and HIT<8>. The NAND logic circuit ND4 may receive the hit signals HIT<9>, HIT<10>, and HIT<11>. The NAND logic circuit ND5 may receive the hit signals HIT<12>, HIT<13>, and HIT<14>. The NAND logic circuit ND6 may receive the outputs of the NAND logic circuits ND1, ND2, and ND3. The NAND logic circuit ND7 may receive the outputs of the NAND logic circuits ND4 and ND5. The NAND logic circuit ND8 may receive the outputs of the NAND logic circuits ND6 and ND7.

When all the hit signals HIT[14:1] are at a high logic level, the combinational logic circuit 930 may generate the pre-repair enable signal REP_ENB at a low logic level and output the repair enable signal REP_EN at a high logic level. Based on the pre-repair enable signal REP_ENB at a low logic level and the repair enable signal REP_EN at a high logic level, it may be determined that the first address bits stored in the first register R1 match the second address bits stored in the second register R2.

When any one of the hit signals HIT[14:1] is at a low logic level, the combinational logic circuit 930 may generate the pre-repair enable signal REP_ENB at a high logic level and output the repair enable signal REP_EN at a low logic level. Based on the pre-repair enable signal REP_ENB at a high logic level and the repair enable signal REP_EN at a low logic level, it may be determined that the first address bits stored in the first register R1 does not match the second address bits stored in the second register R2.

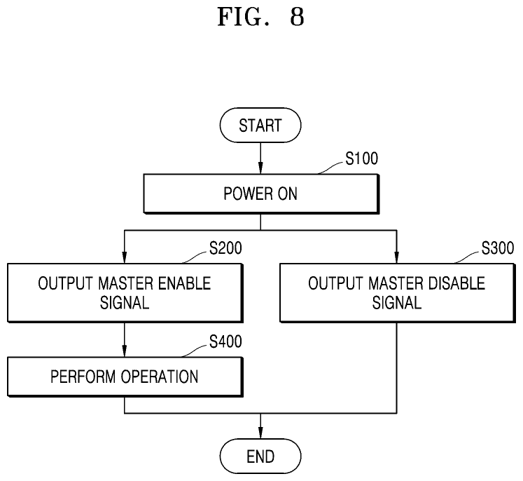

FIG. 8 is a flowchart of an operating method of a memory device, according to implementations.

Referring to FIG. 8, power may be supplied to the memory system 1, and the memory system 1 may be powered on in operation S100. When the memory system 1 is powered on and the level of a power supply voltage driving the memory device 10 is maintained constant, the memory device 10 may generate control signals (e.g., the master enable signal MASTER_EN and the master disable signal MASTER_DIS). When the memory controller 20 provides a write or read command and the address ADDR to the memory device 10, the memory device 10 may operate in the normal mode.

The control logic 300 may generate and output the master enable signal MASTER_EN in operation S200. The control logic 300 may generate and output the master disable signal MASTER_DIS in operation S300. For example, referring to FIG. 3, the control logic 300 may generate and output the master enable signal MASTER_EN and/or the master disable signal MASTER_DIS. For example, the master enable signal (MASTER_EN) and/or the master disable signal (MASTER_DIS) may be defined based on the output state of the control logic 300.

The memory device 10 may perform an operation in operation S400. For example, referring to FIG. 2, when the first repair circuit 201 receives the master enable signal MASTER_EN from the control logic 300, the first repair circuit 201 may perform a repair operation. When the second repair circuit 202 receives the master enable signal MASTER_EN from the control logic 300, the second repair circuit 202 may perform a repair operation.

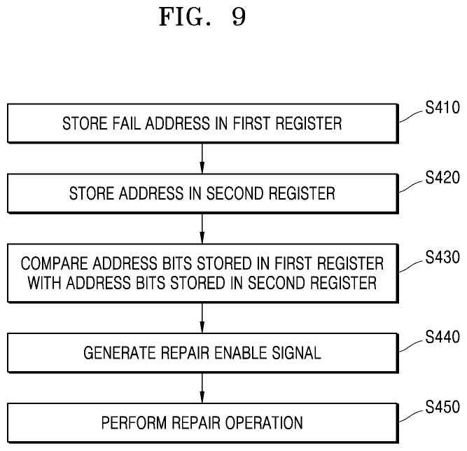

A method of performing, by the repair circuit 200, a repair operation is described with reference to FIG. 9 below.

FIG. 9 is a flowchart of an operating method of a repair circuit, according to implementations.

Referring to FIG. 9, the first register R1 of the fail address memory 921 may store the fail address F_ADDR in operation S410. For example, referring to FIGS. 2 and 7, the first register R1 may store the first address provided from the fuse circuit 910. Here, the first address may be the fail address F_ADDR.

The second register R2 of the fail address memory 921 may store the address ADDR in operation S420. For example, referring to FIGS. 2 and 7, the second register R1 may store the second address provided from the memory controller 20 (in FIG. 1). Here, the second address may be the address ADDR.

The address comparator circuit 922 may compare address bit values stored in the first register R1 with address bit values stored in the second register, respectively, in operation S430. For example, referring to FIGS. 2 and 7, the XNOR logic circuits C1 to C14 of the address comparator circuit 922 may respectively compare the values of the bits <14:1> of the first address stored in the first register R1 with the values of the bits <14:1> of the second address stored in the second register R2 and may output the hit signals.

The combinational logic circuit 930 may generate the repair enable signal REP_EN in repair operation S440. For example, referring to FIG. 7, when all the hit signals HIT[14:1] are at a high logic level, the combinational logic circuit 930 may generate the pre-repair enable signal REP_ENB at a low logic level and output the repair enable signal REP_EN at a high logic level.

The repair circuit 200 may perform a repair operation in operation S450. For example, referring to FIG. 2, the first repair circuit 201 may receive the master enable signal MASTER_EN from the control logic 300 and perform a repair operation.

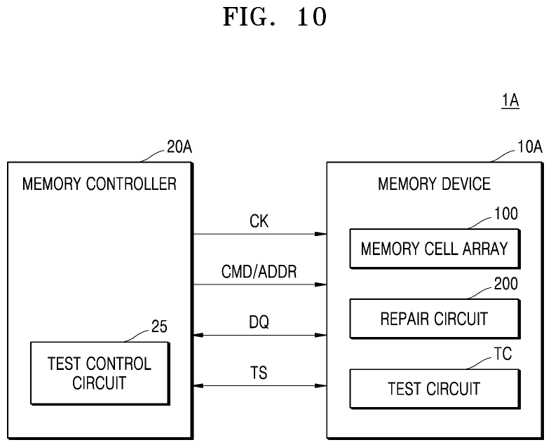

FIG. 10 is a block diagram of a memory system 1A according to implementations. Redundant descriptions given with reference to FIG. 1 are omitted.

The memory system 1A of FIG. 10 may correspond to the memory system 1 of FIG. 1.

Referring to FIG. 10, the memory system 1A may include a memory controller 20A and a memory device 10A. The memory controller 20A may include a test control circuit 25. The memory device 10A may include the memory cell array 100, the repair circuit 200, and a test circuit TC.

The memory system 1A of FIG. 10 is different from the memory system 1 of FIG. 1 in that the memory controller 20A includes the test control circuit 25 and the memory device 10A includes the test circuit TC.

The test control circuit 25 may include various algorithms configuring the memory controller 20A such that the memory controller 20A may normally interoperate with the memory device 10A. For example, codes representing the frequency, timing, driving, detailed operation parameter, etc. of the memory device 10A may be set in the test control circuit 25.

The test circuit TC may generally control test operation of the memory device 10A. The test circuit TC may exchange test signals TS with the memory controller 20A. The test circuit TC may receive a test signal TS from the memory controller 20A and may perform a test operation. For example, the test circuit TC may include a semiconductor chip, such as a field programmable gate array (FPGA), an application specific integrated circuit (ASIC), or an AP.

According to implementations, the memory device 10A may generate control signals (e.g., a master enable signal and a master disable signal). When the memory device 10A operates in the normal mode, the memory device 10A may block leakage current to the repair circuit 200 and/or the test circuit TC by controlling the control signals.

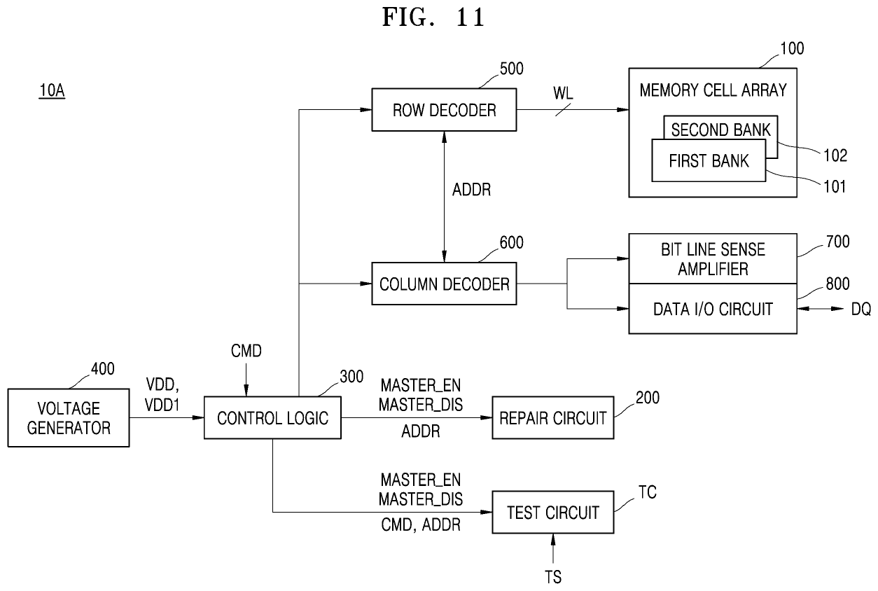

FIG. 11 is a block diagram of the memory device 10A according to implementations. Redundant descriptions given with reference to FIG. 2 are omitted.

The memory device 10A of FIG. 11 may correspond to the memory device 10 of FIG. 2.

Referring to FIG. 11, the memory device 10A may include the memory cell array 100, the control logic 300, the repair circuit 200, the voltage generator 400, the row decoder 500, the column decoder 600, the bit line sense amplifier 700, the data I/O circuit 800, and the test circuit TC.

The control logic 300 may generate and output the master enable signal MASTER_EN and/or the master disable signal MASTER_DIS in response to the command CMD.

Here, the master enable signal MASTER_EN may refer to a control signal, which allows each circuit of the memory device 10A to operate when the memory device 10A operates in the normal mode. For example, when the memory device 10A operates in the normal mode, the test circuit TC may receive the master enable signal MASTER_EN and perform a test operation in response to the master enable signal MASTER_EN. When the test circuit TC receives the master enable signal MASTER_EN, the test circuit TC may be referred to as a used circuit.

The master disable signal MASTER_DIS may refer to a control signal, which does not allow each circuit of the memory device 10A to operate when the memory device 10A operates in the normal mode For example, when the memory device 10A operates in the normal mode, the test circuit TC may receive the master disable signal MASTER_DIS and may not perform a test operation in response to the master disable signal MASTER_DIS. When the test circuit TC receives the master disable signal MASTER_DIS, the test circuit TC may be referred to as an unused circuit.

According to implementations, when the memory device 10A operates in the normal mode, the control logic 300 may generate and provide the master disable signal MASTER_DIS to an unused circuit. Accordingly, the control logic 300 may reduce leakage current to the unused circuit by controlling the master disable signal MASTER_DIS, thereby reducing power consumption of the memory device 10A.

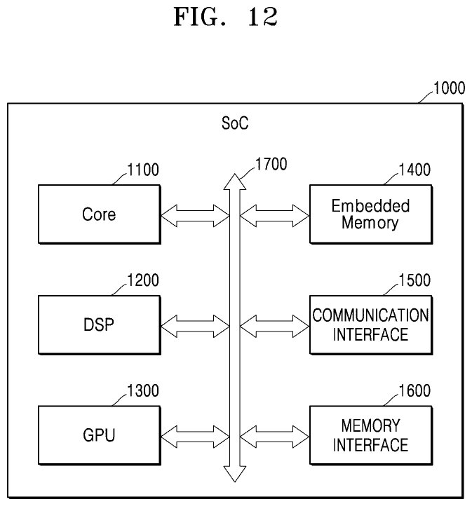

FIG. 12 is a block diagram of a system-on-chip (SoC) 1000 according to implementations.

Referring to FIG. 12, the SoC 1000 may refer to an integrated circuit in which components of a computing system or another electronic system are integrated. For example, an AP as an example of the SoC 1000 may include a processor and components for other functions. The SoC 1000 may include a core 1100, a DSP 1200, a GPU 1300, an embedded memory 1400, a communication interface 1500, and a memory interface 1600. The elements of the SoC 1000 may communicate with one another through a bus 1700.

The core 1100 may process instructions and control the operations of the elements of the SoC 1000. For example, the core 1100 may drive an operating system (OS) by processing a series of instructions and execute applications on the OS. The DSP 1200 may generate useful data by processing a digital signal, for example, provided from the communication interface 1500. The GPU 1300 may generate data, which corresponds to an image output through a display device, from image data provided from the embedded memory 1400 or the memory interface 1600 or may encode the image data. In some implementations, the integrated circuit described above with reference to the drawings may be included in the core 1100, the DSP 1200, the GPU 1300, and/or the embedded memory 1400.

The embedded memory 1400 may store data necessary for the operations of the core 1100, the DSP 1200, and the GPU 1300. The communication interface 1500 may provide an interface for a network communication or one-to-one communication. The memory interface 1600 may provide an interface with a memory, e.g., DRAM or flash memory, outside the SoC 1000.

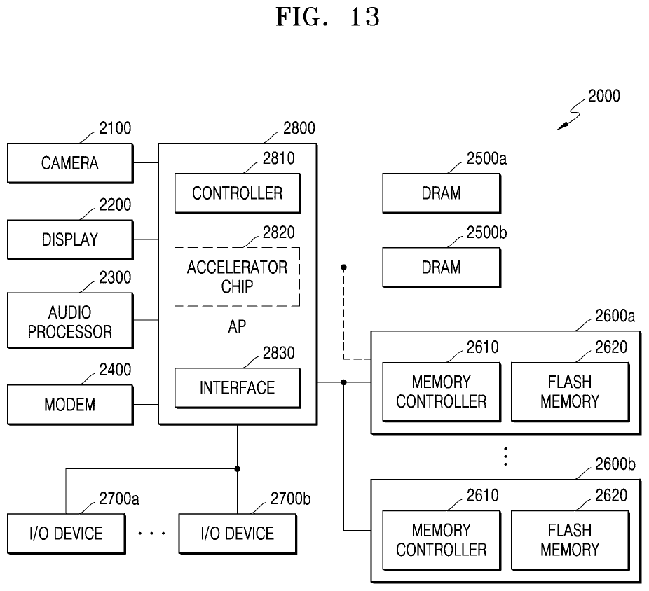

FIG. 13 is a block diagram of a system 2000 illustrating an electronic device including a memory device, according to implementations.

Referring to FIG. 13, the system 2000 may include a camera 2100, a display 2200, an audio processor 2300, a modem 2400, DRAMs 2500a and 2500b, flash memory devices 2600a and 2600b, I/O devices 2700a and 2700b, and an AP 2800. The system 2000 may include a laptop computer, a mobile phone, a smartphone, a tablet PC, a wearable device, a healthcare device, or an Internet of things (IoT) device. The system 2000 may include a server or a PC.

The camera 2100 may shoot a still image or a video under a user's control and store image/video data or transmit the image/video data to the display 2200. The audio processor 2300 may process audio data included in the contents of the flash memory devices 2600a and 2600b or a network. For wired/wireless data communication, the modem 2400 modulates a signal, transmits a modulated signal, and demodulates a received signal to restore an original signal. The I/O devices 2700a and 2700b may include devices, such as universal serial bus (USB) storage, a digital camera, a secure digital (SD) card, a digital versatile disc (DVD), a network adapter, and a touch screen, which provide digital input and/or output functions.

The AP 2800 generally controls operations of the system 2000. The AP 2800 may include a controller 2810, an accelerator block or accelerator chip 2820, and an interface 2830. The AP 2800 may control the display 2200 to display some of the contents stored in the flash memory devices 2600a and 2600b. When the AP 2800 receives user input through the I/O devices 2700a and 2700b, the AP 2800 may perform a control operation corresponding to the user input. The AP 2800 may include an accelerator block, which is a dedicated circuit for artificial intelligence (AI) data operations, or the accelerator chip 2820 may be provided separately from the AP 2800. The DRAM 2500b may be additionally mounted on the accelerator block or the accelerator chip 2820. An accelerator is a functional block that specially performs a certain function of the AP 2800 and may include a GPU that is a functional block specially performing graphics data processing, a neural processing unit (NPU) that is a functional block specially performing AI calculation and inference, and a data processing unit (DPU) that is a functional block specially performing data transmission.

The system 2000 may include a plurality of DRAMs 2500a and 2500b. The AP 2800 may control the DRAMs 2500a and 2500b through commands and mode register setting (MRS), which comply with Joint Electron Device Engineering Council (JEDEC) standards, or may set a DRAM interface protocol and communicate with the DRAMs 2500a and 2500b to use a company's unique functions, such as low voltage, high speed, reliability, and a cyclic redundancy check (CRC) function, and/or an error correction code (ECC) function. For example, the AP 2800 may communicate with the DRAM 2500a through an interface, such as LPDDR4 or LPDDR5, complying with the JEDEC standards, and the accelerator block or the accelerator chip 2820 may set a new DRAM interface protocol and communicate with the DRAM 2500b to control the DRAM 2500b, which has a higher bandwidth than the DRAM 2500a for an accelerator.

Although only the DRAMs 2500a and 2500b are illustrated in FIG. 13, implementations are not limited thereto. Any type of memory, such as phase-change RAM (PRAM), SRAM, magnetic RAM (MRAM), resistance RAM (RRAM), ferroelectric RAM (FRAM), or hybrid RAM, which satisfies the requirements of a bandwidth, a response speed, and/or a voltage for the AP 2800 or the accelerator chip 2820, may be used. The DRAMs 2500a and 2500b have relatively less latency and bandwidth than the I/O devices 2700a and 2700b or the flash memory devices 2600a and 2600b. The DRAMs 2500a and 2500b may be initialized when the system 2000 is powered on and may be loaded with an OS and application data to be used as a temporary storage of the OS and the application data or may be used as a space for execution of various kinds of software code.

The four fundamental arithmetic operations, i.e., addition, subtraction, multiplication, and division, vector operations, address operation, or fast Fourier transform (FFT) operations may be performed in the DRAMs 2500a and 2500b. Functions for executions used for inference may also be performed in the DRAMs 2500a and 2500b. Here, the inference may be performed during a deep learning algorithm using an artificial neural network. The deep learning algorithm may include a training phase, in which a model is trained using various data, and an inference phase, in which data is recognized using the trained model. In implementations, an image shot by a user through the camera 2100 may undergo signal processing and may be stored in the DRAM 2500b, and the accelerator block or the accelerator chip 2820 may perform an AI data operation using data stored in the DRAM 2500b and a function used for inference to recognize the data.

The system 2000 may include a plurality of storages or flash memory devices 2600a and 2600b, which have a larger capacity than the DRAMs 2500a and 2500b. The accelerator block or the accelerator chip 2820 may perform a training phase and an AI data operation using the flash memory devices 2600a and 2600b. In implementations, each of the flash memory devices 2600a and 2600b may include a memory controller 2610 and a flash memory 2620 and may allow the AP 2800 and/or the accelerator chip 2820 to efficiently perform a training phase and an inference AI data operation using an arithmetic unit included in the memory controller 2610. The flash memory devices 2600a and 2600b may store images shot through the camera 2100 or data received from a data network. For example, the flash memory devices 2600a and 2600b may store augmented and/or virtual reality contents, high definition (HD) contents, or ultra-high definition (UHD) contents.

In the system 2000, the DRAMs 2500a and 2500b may perform an operating method of the memory device described above with reference to FIGS. 1 to 12. The operating method of the memory device may include generating and outputting a master enable signal and a master disable signal when the memory device operates in the normal mode. A control logic may provide the master enable signal to a first repair circuit that is a used circuit and may provide the master disable signal to a second repair circuit that is an unused circuit. The control logic may reduce leakage current flowing in the unused circuit and power consumption of the memory device by generating and providing the master disable signal to the unused circuit.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the memory device has been particularly shown and described with reference to implementations thereof, it will be understood that various changes in form and details may be made therein without departing from the spirit and scope of the following claims.

What is claimed is:

1. A memory device comprising:
a memory cell array including a first memory bank and a second memory bank;
a control logic configured to control operations of the memory cell array and generate a master enable signal and a master disable signal;
a first repair circuit configured to perform a repair operation on memory cells of the first memory bank; and
a second repair circuit configured to perform the repair operation on memory cells of the second memory bank,
wherein the first repair circuit is configured to operate based on the control logic generating the master enable signal in a normal mode, and
wherein the control logic is configured to block a first current to the second repair circuit based on the master disable signal in the normal mode.

2. The memory device of claim 1, wherein the master disable signal is configured to block a power supply voltage supplied to the second repair circuit.

3. The memory device of claim 1, wherein
the first repair circuit includes:
a fuse circuit storing a fail address showing fail characteristics in the memory cell array;
a content-addressable memory (CAM) cell configured to compare an address with the fail address and output hit signals; and
a combinational logic circuit configured to output a repair enable signal, based on the hit signals,
wherein the CAM cell includes:
a fail address memory including a first register storing a first address and a second register storing a second address; and
an address comparator circuit configured to respectively compare address bit values stored in the first register with address bit values stored in the second register and configured to output the hit signals.

4. The memory device of claim 3, wherein
each of the first register and the second register includes one of a static random-access memory (SRAM) cell and a dual interlocked storage cell SRAM cell.

5. The memory device of claim 3, wherein
the address comparator circuit is configured to output the hit signals by using XNOR logic circuits, wherein the address bit values from the first register and the address bit values from the second register are respectively input into the XNOR logic circuits.

6. The memory device of claim 3, wherein
the repair enable signal is configured to be at a high logic level when the first address matches the second address, and
the repair enable signal is configured to be at a low logic level when the first address does not match the second address.

7. The memory device of claim 1, wherein
the control logic includes:
a first inverter configured to receive a master signal and a first power supply voltage; and
a first transistor configured to receive a power supply voltage, and
wherein the first transistor is configured to, based on a level of the first power supply voltage being higher than a level of the power supply voltage, be turned on and output the master enable signal.

8. A memory device comprising:
a memory cell array including a plurality of memory cells;
a control logic configured to control operations of the memory cell array and generate a master enable signal and a master disable signal; and
a first circuit configured to perform a first operation on the plurality of memory cells,
wherein, based on the first circuit operating as a repair circuit,
the first circuit is configured to operate based on the master enable signal in a normal mode, and
the control logic is configured to block a first current to the first circuit based on the master disable signal in the normal mode.

9. The memory device of claim 8, wherein the master disable signal is configured to block a power supply voltage supplied to the first circuit.

10. The memory device of claim 8, wherein the first circuit corresponds to one of the repair circuit or a test circuit.

11. The memory device of claim 10, wherein,
when the first circuit corresponds to the repair circuit,
the first circuit includes:
a fuse circuit storing a fail address showing fail characteristics in the memory cell array;
a content-addressable memory (CAM) cell configured to compare an address with the fail address and output hit signals; and
a combinational logic circuit configured to output a repair enable signal, based on the hit signals,
wherein the CAM cell includes:
a fail address memory including a first register storing a first address and a second register storing a second address; and
an address comparator circuit configured to respectively compare address bit values stored in the first register with address bit values stored in the second register and configured to output the hit signals.

12. The memory device of claim 11, wherein
the fail address memory includes one of a static random-access memory (SRAM) cell and a dual interlocked storage cell SRAM cell.

13. The memory device of claim 11, wherein
the address comparator circuit is configured to output the hit signals by using XNOR logic circuits, wherein the address bit values from the first register and the address bit values from the second register are respectively input into the XNOR logic circuits, and
the combinational logic circuit is configured to
output the repair enable signal at a high logic level when the first address matches the second address and
output the repair enable signal at a low logic level when the first address does not match the second address.

14. The memory device of claim 10, wherein
the control logic includes:
a first inverter configured to receive a master signal and a first power supply voltage; and
a first transistor configured to receive a power supply voltage, and
wherein the first transistor is configured to, based on a level of the first power supply voltage being higher than a level of the power supply voltage, be turned on and output the master enable signal.

15. The memory device of claim 10, wherein,
when the memory device is operating in the normal mode,
wherein, when the first circuit corresponds to the repair circuit, the first circuit is configured to perform a repair operation, based on the master enable signal, and is configured to not perform the repair operation, based on the master disable signal, and
wherein, when the first circuit corresponds to the test circuit, the first circuit is configured to perform a test operation, based on the master enable signal, and is configured to not perform the test operation, based on the master disable signal.

16. An operating method of a memory device, the operating method comprising:
applying a power supply voltage to the memory device according to power-on of the memory device;
generating and outputting a master enable signal and a master disable signal, based on the power supply voltage;
performing a repair operation based on a control logic generating the master enable signal in a normal mode; and
not performing the repair operation based on the control logic generating the master disable signal based on the memory device operating in the normal mode.

17. The operating method of claim 16, wherein
performing the operation of the memory device includes:
storing a first address in a first register of a repair circuit;
storing a second address in a second register of the repair circuit;
respectively comparing address bit values stored in the first register with address bit values stored in the second register and outputting hit signals; and
generating and outputting a repair enable signal, based on the hit signals.

18. The operating method of claim 17, further comprising:
outputting the hit signals by using XNOR logic circuits into which the address bit values from the first register and the address bit values from the second register are respectively input.

19. The operating method of claim 17, wherein
generating and outputting the repair enable signal include:
outputting the repair enable signal at a high logic level when the first address matches the second address; and
outputting the repair enable signal at a low logic level when the first address does not match the second address.

20. The operating method of claim 16, wherein the master disable signal is configured to block the power supply voltage supplied to the memory device.
